(19) United States
(12) Patent Application Publication
(10) Pub. No.: US 2025/0022937 A1
(43) Pub. Date: Jan. 16, 2025

(54) METHOD AND SYSTEM FOR VERTICAL FETS FABRICATED ON AN ENGINEERED SUBSTRATE

(71) Applicant: Qromis, Inc., Santa Clara, CA (US)

(72) Inventors: Vladimir Odnoblyudov, Danville, CA (US); Cem Basceri, Los Gatos, CA (US)

(73) Assignee: Qromis, Inc., Santa Clara, CA (US)

(21) Appl. No.: 18/768,904

(22) Filed: Jul. 10, 2024

Related U.S. Application Data
(60) Provisional application No. 63/526,758, filed on Jul. 14, 2023.

(51) Int. Cl. H01L 29/66; H01L 21/768

(52) U.S. Cl. CPC H01L 29/66446; H01L 21/768

(57) ABSTRACT

A method of fabricating a semiconductor device includes providing an engineered substrate. The method further includes forming an epitaxial gallium nitride (GaN) layer coupled to the engineered substrate, forming a plurality of trenches in the epitaxial GaN layer, and forming a plurality of gates in the trenches. The method further includes forming a plurality of sources coupled to the epitaxial GaN layer, forming an interconnect structure on the gates and sources, forming a metal bonding layer on the interconnect structure, bonding a conductive carrier to the metal bonding layer, removing the engineered substrate, forming a drain layer on the back surface of the epitaxial GaN layer, etching at least one portion of the epitaxial GaN layer and the interconnect structure to form at least one gate pad recess and expose the embedded metal track; and forming at least one gate electrode in the gate pad recess.

### CROSS-REFERENCES TO RELATED APPLICATIONS

This application claims priority to U.S. Provisional Patent Application No. 63/526,758, filed on Jul. 14, 2023, the disclosure of which is hereby incorporated by reference in its entirety for all purposes.

### BACKGROUND OF THE INVENTION

Field Effect Transistor (FET) devices based on gallium nitride (GaN) are typically grown epitaxially on substrates such as sapphire. This heteroepitaxial growth process, given the different materials of the substrate and epitaxial layers, can result in various adverse effects. These may include decreased uniformity and detriments in parameters linked to the electronic and mechanical attributes of the epitaxial layers. The GaN-based FET devices might thereby suffer performance and reliability issues. Therefore, there's a recognized need in the field for enhanced methods and systems concerning epitaxial growth processes and substrate structures in the context of GaN-based FETs.

### SUMMARY OF THE INVENTION

The present invention relates generally to a method for fabricating a semiconductor device. More specifically, the present invention relates to a method fabricating vertical field effect transistor (FET) integrated circuits, such as gallium nitride (GaN) integrated circuits, using an engineered substrate and a plurality of groups of epitaxial layers, where the coefficient of thermal expansion (CTE) of the engineered substrate substantially matches the CTE of the epitaxial layers. Merely by way of example, the present disclosure relates to methods of fabricating vertical FETs by using an engineered substrate. The methods and techniques can be applied to a variety of semiconductor processing operations. It is noted that although GaN vertical FETs integrated circuits are used as examples in some embodiments described below, other compound semiconductor-based transistor integrated circuits may be made using the methods and techniques disclosed here.

One general aspect includes a method for fabricating a semiconductor device. The method also includes providing an engineered substrate including: a polycrystalline ceramic core, a barrier layer coupled to the polycrystalline ceramic core, a bonding layer coupled to the barrier layer, and a substantially single crystalline layer coupled to the bonding layer. The method also includes forming an epitaxial gallium nitride layer coupled to the substantially single crystalline layer. The method also includes forming a plurality of trenches in the epitaxial gallium nitride layer. The method also includes forming a plurality of gates, each of the plurality of gates being disposed in one of the plurality of trenches. The method also includes forming a plurality of sources coupled to the epitaxial gallium nitride layer. The method also includes forming an interconnect structure on the plurality of gates and the plurality of sources, where the interconnect structure may include: an embedded metal track, a first set of routing structures passing through the interconnect structure and electrically connecting the plurality of gates to the embedded metal track, and a second set of routing structures passing through the interconnect structure. The method also includes forming a metal bonding layer on the interconnect structure, where the second set of routing structures electrically connect the plurality of sources to the metal bonding layer. The method also includes bonding a conductive carrier to the metal bonding layer. The method also includes removing the engineered substrate to expose a back surface of the epitaxial gallium nitride layer. The method also includes forming a drain layer on the back surface of the epitaxial gallium nitride layer. The method also includes etching at least one portion of the epitaxial gallium nitride layer and the interconnect structure to form at least one gate pad recess and expose the embedded metal track. The method also includes forming at least one gate electrode in the at least one gate pad recess.

Implementations may include one or more of the following features. The method may include forming at least one gate pad attached to the at least one gate electrode. The at least one gate pad recess may include two gate pad recesses, and the at least one gate pad may include two gate pads. The interconnect structure may include a first metal stack may include a first plated bonding metal layer, the metal bonding layer may include a second metal stack may include a second plated bonding metal layer, and the metal bonding layer is bonded to the interconnected structure by bonding the second plated bonding metal layer to the first plated bonding metal layer. A depth of at least one of the plurality of trenches ranges from 0.5 m to 2 m. A depth of the at least one gate pad recess is between 5 m and 30 m. The substantially single crystalline layer may include substantially single crystalline silicon. The substantially single crystalline layer may include substantially single crystalline gallium nitride. The substantially single crystalline layer may include substantially single crystalline silicon carbide. The conductive carrier may include a doped silicon carrier. The doped silicon carrier is p-type. The doped silicon carrier is n-type. The drain layer is formed without patterning. The conductive carrier may include a thick plated metal layer. The thick plated metal layer is characterized by a thickness ranging from 20 um to 200 um.

Numerous benefits are achieved by way of the present disclosure over conventional techniques. For example, embodiments of the present invention provide vertical FETs suitable for high power operation with vertical current flow between the source and drain while gate electrodes operating at lower voltages are provided at one or more corners of the device. Embodiments of the present invention are applicable to Fin-based FETS (FinFeTs) as well as trench metal oxide semiconductor FETS (MOSFETs). These and other embodiments of the disclosure, along with many of its advantages and features, are described in more detail in conjunction with the text below and corresponding figures.

### BRIEF DESCRIPTION OF THE DRAWINGS

FIG. 1 is simplified flowchart illustrating a method of forming a transistor integrated circuit according to some embodiments of the present invention.

FIGS. 2A-2J are simplified schematic cross-sectional diagrams illustrating the intermediate steps of the method shown in FIG. 1 according to an embodiment of the present invention.

FIG. 3 is a simplified schematic diagram illustrating an engineered substrate according to an embodiment of the present invention.

FIGS. 4A-4D are simplified schematic diagrams illustrating schematic top views of gates according to different embodiments of the present invention.

FIG. 5 is a simplified schematic diagram illustrating a schematic cross-sectional view of the metal stack for bonding according to one embodiment of the present invention.

FIG. 6A-6B are simplified schematic diagrams illustrating schematic cross-sectional views of the back surface of the epitaxial GaN layer according to different embodiments of the present invention.

### DETAILED DESCRIPTION OF SPECIFIC EMBODIMENTS

The present invention relates generally to a method fabricating a semiconductor device. More specifically, the present invention relates to a method fabricating vertical field effect transistor (FET) integrated circuits, such as gallium nitride (GaN) integrated circuits, using an engineered substrate and a plurality of groups of epitaxial layers, where the coefficient of thermal expansion (CTE) of the engineered substrate substantially matches the CTE of the epitaxial layers. Merely by way of example, the present disclosure relates to methods of fabricating vertical FETs by using an engineered substrate, wherein the vertical FETs comprise a plurality of sources surrounding a plurality of gates, and a drain layer formed on a surface of an epitaxial gallium nitride layer and at least one gate electrode exposed on the surface of the epitaxial gallium nitride layer. The methods and techniques can be applied to a variety of semiconductor processing operations. It is noted that although GaN vertical FETs integrated circuits are used as examples in some embodiments described below, other compound semiconductor-based transistor integrated circuits may be made using the methods and techniques disclosed here.

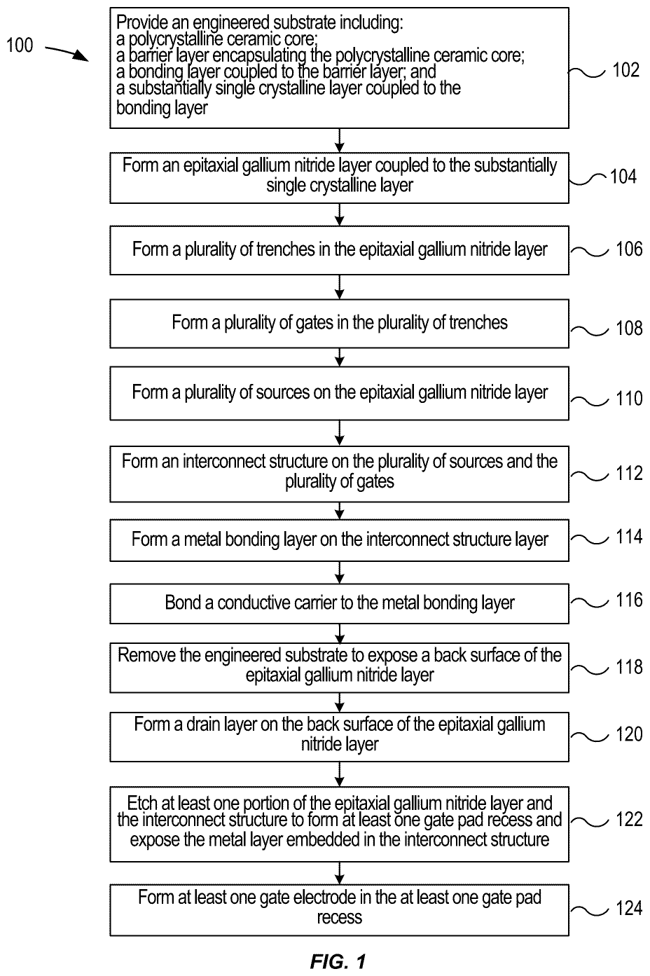

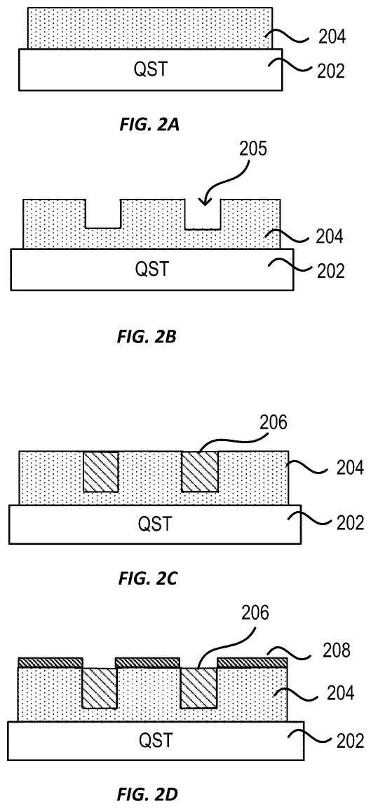

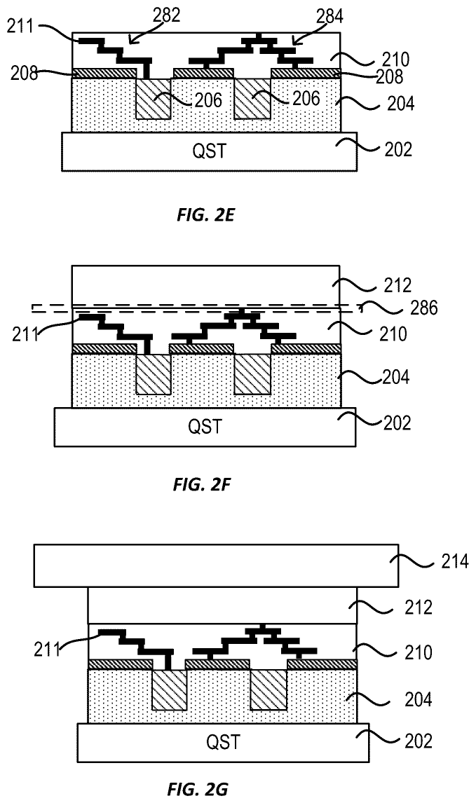

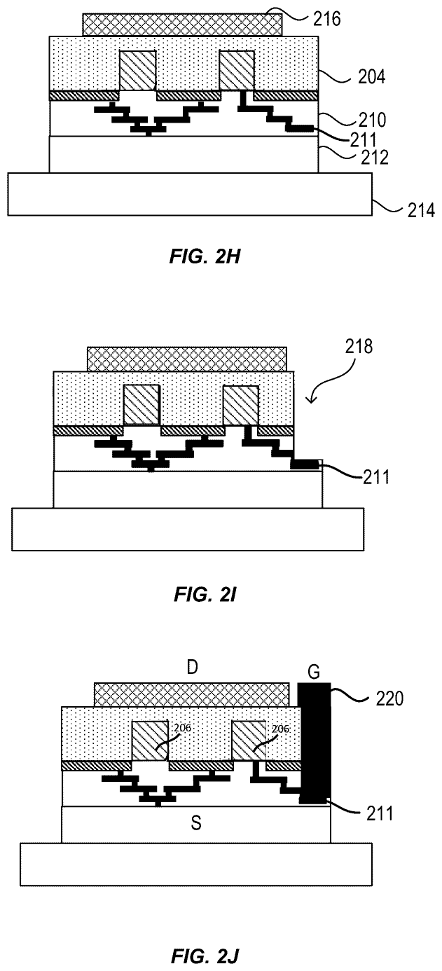

FIG. 1 is a simplified flowchart illustrating a method 100 of forming a vertical FET integrated circuit according to some embodiments of the present invention. FIG. 2A-2J are simplified schematic cross-sectional diagrams illustrating the intermediate steps of the method shown in FIG. 1 according to an embodiment of the present invention.

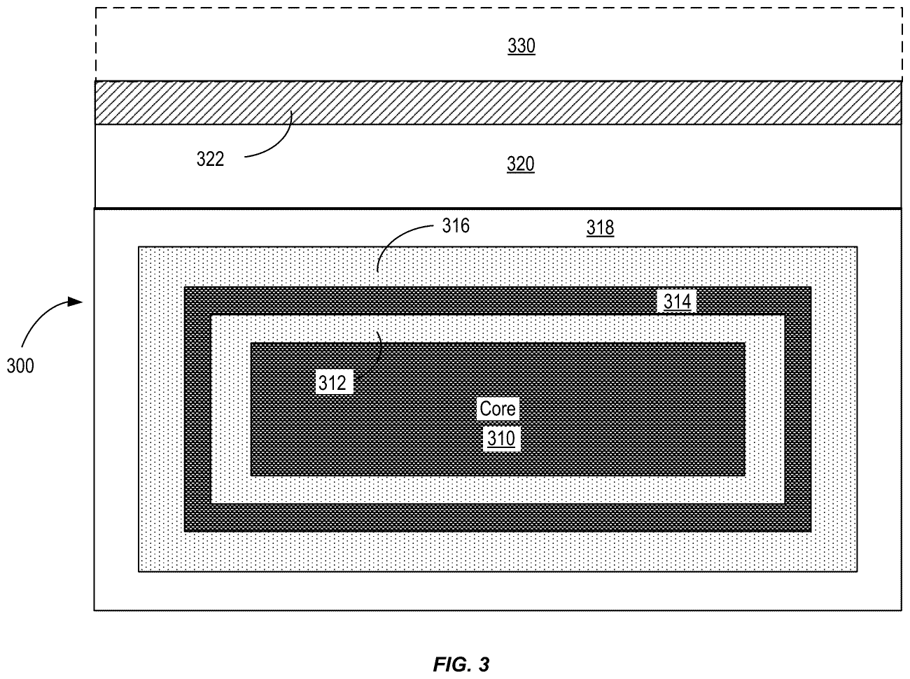

Referring to FIGS. 1 and 2A, at step 102, an engineered substrate 202 is provided. An example of the engineered substrate will be discussed below with reference to FIG. 3. As will be discussed in greater detail below, the engineered substrate 202/300 may comprise a polycrystalline ceramic core 310, a barrier layer 318 encapsulating the polycrystalline ceramic core 310, a bonding layer 320 coupled to the barrier layer 318, and a substantially single crystalline layer 322 coupled to the bonding layer 320. In some embodiments, the substantially single crystalline layer 322 is a substantially single crystalline silicon layer 322. In another embodiment, the substantially single crystalline layer 322 is a substantially single crystalline gallium nitride layer 322. In yet another embodiment, the substantially single crystalline layer 322 is a substantially single crystalline silicon carbide layer 322. Although the substantially single crystalline silicon layer 322 is primarily used as one example below, it should be appreciated that the techniques set forth in the disclosure are also applicable to the substantially single crystalline gallium nitride layer and the substantially single crystalline silicon carbide layer.

In some embodiments, the polycrystalline ceramic core 310 of the engineered substrate 202/300 may include polycrystalline aluminum gallium nitride (AlGaN), polycrystalline gallium nitride (GaN), polycrystalline aluminum nitride (AlN), polycrystalline silicon carbide (SiC), or a combination thereof. In some embodiments, the barrier layer 318 may include SiₓO_{y}, SiₓN_{y}, SiₓO_{y}N_{z}, SiCN, SION, AlN, SiC, or a combination thereof. In some embodiments, the bonding layer 320 may include an oxide layer, such as a silicon oxide layer. In one embodiment, the single crystal silicon layer 322 includes a silicon layer that may be suitable for use as a growth layer during epitaxial growth process for the formation of epitaxial materials as discussed below.

In some embodiments, as illustrated in FIG. 3, the engineered substrate 202/300 may further include a first adhesion layer 312 coupled to the polycrystalline ceramic core 310, a conductive layer 314 coupled to the first adhesion layer 312, and a second adhesion layer 316 coupled to the conductive layer 314, where the first adhesion layer 312, the conductive layer 314 and the second adhesion layer 316 are disposed between the polycrystalline ceramic core 310 and the barrier layer 318. In some embodiments, the first adhesion layer 312 may comprise a first tetraethyl orthosilicate (TEOS) oxide layer, and the second adhesion layer 316 may comprise a second TEOS oxide layer. The conductive layer 314 may comprise a polysilicon layer. In some embodiments, the engineered substrate 300 may further include a nucleation layer coupled to the substantially single crystalline silicon layer 322 for facilitating the formation of the epitaxial device layers.

At step 104, an epitaxial gallium nitride (GaN) layer 204 coupled to the engineered substrate 202 is formed. In some embodiment, the epitaxial GaN layer 204 is coupled to the substantially single crystalline silicon layer 322 of the engineered substrate 202/300 as illustrated in FIG. 3. Although an epitaxial GaN layer 204, for example, an n-type GaN layer, is illustrated in FIG. 2A, it will be appreciated that other suitable epitaxial layers including GaN-based layers, such as AlGaN, InGaN, and the like, can be utilized according to alternative embodiments of the present invention. Moreover, although a single epitaxial GaN layer 204 is illustrated in FIG. 2A, it will be appreciated that multiple epitaxial layers, including n-p-i-n structures, n-i-n structures, including buffer layers, drift layers, contact layers, etc., and other multilayer epitaxial structures can be utilized and are included within the scope of the present invention.

According to some embodiments, the epitaxial GaN layer 204 may be formed by thin film deposition techniques such as chemical vapor deposition (CVD), (including metal-organic CVD (MOCVD), low-pressure CVD (LPCVD), plasma-enhanced CVD (PECVD), atomic-layer CVD (ALCVD)), hydride vapor phase epitaxy (HVPE), atomic layer deposition (ALD), molecular beam epitaxy (MBE), or a combination thereof.

The concentration and thickness of the epitaxial GaN layer 204 are determined by the device design requirements, such as its desired electrical characteristics. In some embodiments, the epitaxial GaN layer 204 may have a relatively high N-type doping concentration in one or more layers, for example n-type doping ranging from about 1×10¹⁸ cm⁻³ to 1-2×10¹⁹ cm⁻³ for contact layers, p-type doping ranging from about 1×10¹⁹ cm⁻³ to 1-2×10²⁰ cm⁻³, and doping ranging from about 1×10¹⁵ cm⁻³ to 5×10¹⁶ cm⁻³ for drift layers and the epitaxial GaN layer 204 may have a thickness ranging from about 5 μm to about 30 μm. By using a CTE-matched engineered substrate 202, epitaxial growth of a relatively thick drift region with low dislocation density may be possible. In other words, the relatively thick drift region is enabled by CTE matching of the engineered substrate 202 and the epitaxial GaN layer 204. A thicker drift region may afford lower leakage current and a much higher breakdown voltage, as well as many other advantages.

Referring to FIGS. 1 and 2B, at step 106, a plurality of trenches 205 are formed in the epitaxial GaN layer 204. In some embodiments, the trenches 205 may be formed using suitable etching processes such as wet etching and dry etching. In some embodiments, the size of the trenches 205 may be adjusted. For example, the depth of the trenches 205 may range from 0.5 μm to 2 μm, whereas the width of the trenches 205 may range from 0.125 μm to 1 μm.

Referring to FIGS. 1 and 2C, at step 108, a plurality of gates 206 are formed in the plurality of trenches 205. In some embodiments, the plurality of gates 206 may include doped polysilicon, gallium arsenide (GaAs), or GaN. In some embodiments, the plurality of gates 206 may include metals or metallic compounds, such as Ti, TiN, Ti/Al, Ni, Pt, etc, or contain multilayered metal stacks. As per some embodiments, multiple gates could be created through the deposition of a gate layer, followed by a Chemical Mechanical Polishing (CMP) process to remove the excess gate layer outside the plurality of trenches 205. This process may also establish a substantially planar upper surface free of voids, particles, or features for the epitaxial GaN layer 204.

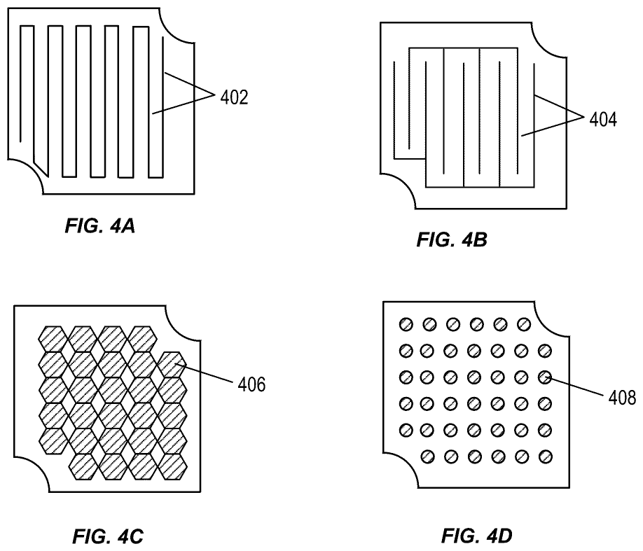

According to some embodiments, the gates 206 may be arranged in diverse configurations within the epitaxial gallium nitride layer 204. FIGS. 4A-4B illustrate top views of the plurality of trenches 205 in accordance with some embodiments. As shown in FIGS. 4A-4B, the trenches 205 may take the form of parallel line structures 402 or 404. The parallel line structures 402 are connected, while the parallel line structures 404 includes two subsets of connected parallel line structures. FIGS. 4C-4D illustrate top views of the plurality of trenches 205 in accordance with other embodiments. As shown in FIGS. 4C and 4D, the plurality of gates 206 may also be arranged in specific geometric patterns, for example, hexagonal patterns 406 arranged in an array (FIG. 4C) or circular patterns 408 arranged in an array (FIG. 4D). The specific geometric patterns can improve current flow, reduce parasitic capacitance, increase current density, and enhance heat dissipation. One of ordinary skill in the art would recognize many variations, modifications, and alternatives.

Referring to FIGS. 1 and 2D, at step 110, a plurality of sources 208 are formed on the epitaxial gallium nitride layer 204. In the embodiment shown in FIG. 2D, each of the plurality of sources 208, except those proximate to the terminal ends, is disposed between two adjacent trenches of the plurality of trenches 205. According to some embodiments, the formation of the plurality of sources 208 may involve several steps, including, for example, forming trenches in a dielectric layer, forming sources in the trenches, CMP.

Referring to FIGS. 1 and 2E, at step 112, an interconnect structure 210 is formed on the plurality of sources 208 and the plurality of gates 206. The interconnect structure 210 is formed by multiple interlayer dielectric (ILD) layers. The plurality of gates 206 are routed together by a first set of routing structures 282 that passes through the interconnect structure 210. The first set of routing structures 282 includes metal tracks extending horizontally and vias extending vertically, which are made of, for example, copper. A plurality of sources 208 are routed together by a second set of routing structures 284 that passes through the interconnect structure 210. Likewise, the second set of routing structures 284 includes metal tracks extending horizontally and vias extending vertically, which are made of, for example, copper.

The plurality of gates 206 are electrically connected to at least a metal track 211 embedded in the interconnect structure 210 via the first set of routing structures 282. In one embodiment, the metal track 211 is at a top metal layer (e.g., a third metal layer in the example shown in FIG. 2E) in the interconnect structure 210. In the example shown in FIG. 2E, the metal track 211 is located at a peripheral area of the interconnect structure 210 in the horizontal plane. In one embodiment, the peripheral area is a corner area of a rectangular area.

The second set of routing structures 284 electrically connects the plurality of sources 208 to a surface of the interconnect structure 210. This surface may be opposite to the epitaxial gallium nitride layer 204. The second set of routing structures 284 establish an electrical path from the plurality of sources 208 to a metal bonding layer 212, which will be discussed below with reference to FIG. 2F.

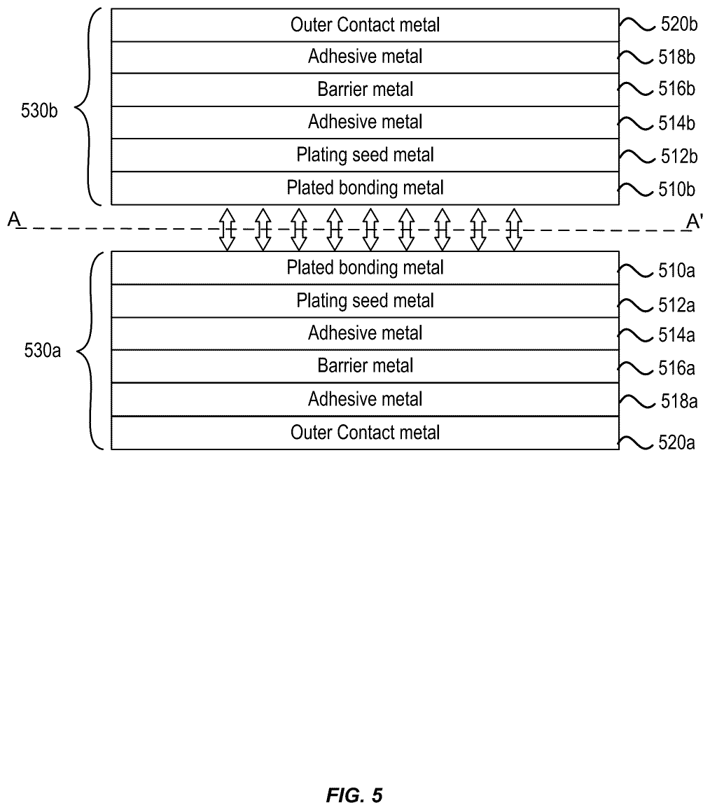

Referring to FIGS. 1 and 2F, at step 114, a metal bonding layer 212 is formed on the interconnect structure 210. In one embodiment, the metal bonding layer 212 and the interconnect structure 210 each include metal stacks facing each other and are bonded together by means of the metal stacks. FIG. 5 illustrates a schematic cross-sectional view of an embodiment of the interface 286 between the metal bonding layer 212 and the interconnect structure 210 of FIG. 2F.

As shown in FIG. 5, the interconnect structure 210 comprises a first metal stack 530a at a surface opposite to the sources 208, and the metal bonding layer 212 comprises a second metal stack 530b at a surface opposite to electrically conductive carrier 214, which will be discussed below with reference to FIG. 2G. Both the first and second metal stacks 530a and 530b have multiple layers and are disposed in a mirror image arrangement with respect to the line A-A′ shown in FIG. 5. The first and second metal stacks 530a and 530b are bonded together, thereby bonding the metal bonding layer 212 to the interconnect structure 210.

In the example shown in FIG. 5, the first metal stack 530a may include a first plating seed metal layer 512a coupled to the first plated bonding metal layer 510a, a first adhesive metal layer 514a coupled to the first plating seed metal layer 512a, a first barrier metal layer 516a coupled to the first adhesive metal layer 514a, a second adhesive metal layer 518a coupled to the first barrier layer metal 516a, and a first outer contact metal layer 520a coupled to the second adhesive metal layer 518a.

Similarly, in a mirror image arrangement, the second metal stack 530b may include a second plating seed metal layer 512b coupled to the second plated bonding metal layer 510b, a third adhesive metal layer 514b coupled to the second plating seed metal layer 512b, a second barrier metal layer 516b coupled to the third adhesive metal layer 514b, a fourth adhesive metal layer 518b coupled to the second barrier metal layer 516b, and a second outer contact metal layer 520b coupled to the fourth adhesive metal layer 518b.

The first and second plated bonding metal layers 510a and 510b are bonded together as indicated by the arrows shown in FIG. 5. In some embodiments, the first and second plated bonding metal layers 510a and 510b comprise Cu, Au, Au/Ni, NiSn alloy, or the like. In some embodiments, the first and second plating seed metal layers 512a and 512b comprise Cu. In some embodiments, the first, second, third, and fourth adhesive layers 514a, 518a, 514b, and 518b comprise Ti. In some embodiments, the first and second barrier metal layer 516a and 516b comprise TiN, TaN, or Pt. It should be appreciated that these example are not intended to be limiting. Since both the first metal stack 530a and the second metal stack 530b include multiple metal layers, a electrical path is established between the second set of routing structures 284, which is electrically connected to the first metal stack 530, and the metal bonding layer 212.

The specific type of metals used for the other metal layers in the first metal stack 530a and the second metal stack 530b can vary widely, depending on the requirements of the device. The metals that may be employed include copper, aluminum, gold, tungsten, and various alloys thereof. Various deposition techniques can be used to form the first metal stack 530a and the second metal stack 530b, including physical vapor deposition (PVD), chemical vapor deposition (CVD), and electroplating, among others.

Referring to FIGS. 1 and 2G, according to some embodiments, at step 116, a conductive carrier 214 is bonded to the metal bonding layer 212. In one embodiment, the conductive carrier 214 may be an electrically conductive silicon carrier. The conductive carrier 214 may be doped, for example, with p-type or n-typed dopants. The conductive carrier 214 may be bonded to the metal bonding layer 212 using an epoxy. The conductive carrier 214 provides a base when the engineered substrate 202 is later removed, as will be discussed below with reference to FIG. 2H. In other embodiments, the conductive carrier 214 can be a metal structure, for example, including plated metals. In yet other embodiments, the conductive carrier 214 comprises a thick plated metal layer (e.g., having a thickness ranging from 20 um to 200 um) plated onto the metal bonding layer 212. In one implementation, the thick plated metal layer is plated onto a plated bonding metal (like the plated bonding metal layer 510a shown in FIG. 5) at a surface of the metal bonding layer 212 opposite to the interconnect structure 210. As a result, there is no need for a metal stack (like the second metal stack 530b shown in FIG. 5). One of ordinary skill in the art would recognize many variations, modifications, and alternatives.

Referring to FIGS. 1 and 2H, according to some embodiments, at step 118, the engineered substrate 202 is removed to expose the back surface of the epitaxial GaN layer 204. The engineered substrate 202 may be removed, for example, by mechanical polishing, dry etching, wet etching, or a liftoff process using an etching chemical such as hydrofluoric acid (HF) or sulfuric acid (H₂SO₄). Because the epitaxial GaN layer 204 is formed on substantially CTE-matched engineered substrate 202, the epitaxial GaN layer 204 may not curl under stress after the engineered substrate 202 is removed.

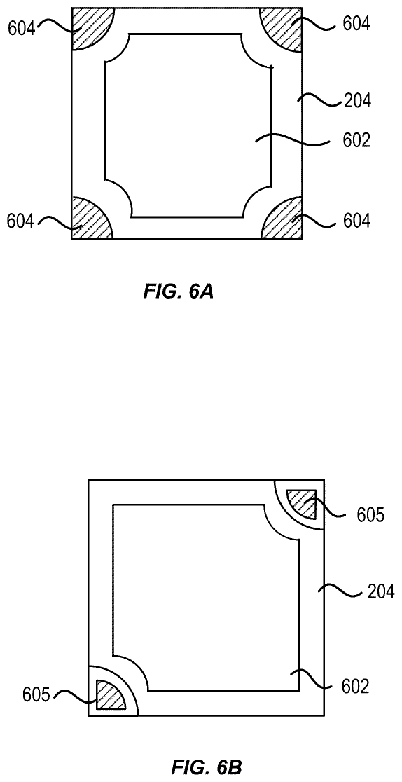

Referring to FIGS. 1 and 2H, after removal of the engineered substrate 202, the device structure may be flipped or inverted, and at step 120, a drain layer 216 is formed. The drain layer 216 is coupled to the back surface of the epitaxial GaN layer 204. In some embodiments, the drain layer 216 may be a blanket drain layer, which is a continuous, uniform layer of material that serves as the drain pad for a transistor. The blanket drain layer may be heavily doped to be conductive. In one embodiment, the drain layer 216 is not patterned. The drain layer 216 may serve as a drain electrode. In the examples as illustrated in FIGS. 6A and 6B, according to some embodiments, the drain electrode 602 may be disposed in the center of the back surface of the epitaxial GaN layer 204, without direct contact with gate electrodes 604 (or gate pads in some embodiments).

Referring to FIGS. 1 and 2I, according to some embodiments, at step 122, at least one portion of the epitaxial gallium nitride layer 204 and the interconnect structure 210 are etched to form at least one gate pad recess 218 and expose the metal stack 211 that is embedded in the interconnect structure 210. The gate pad recess 218 may be located in various areas, for example, at the corner of the epitaxial gallium nitride layer 204. The depth of the recess may be tens of microns, for example, between 5 μm and 30 μm and is suitable to expose the metal stack 211 electrically connected to the gates 206. The width of the recess may be on the order of hundreds of microns, for example, between 80 μm and 300 μm.

Referring to FIGS. 1 and 2J, after the gate pad recess 218 is formed, at step 124, at least one gate electrode 220 is formed in the at least one gate pad recess 218. The at least one gate electrode 220 fills the at least one gate pad recess 218 and may have an excess portion (i.e., a “cap”) outside the at least one gate pad recess 218. This allows for easier and more reliable electrical connection, for example, using a wire bond. The gate electrode 220 is designed to be robust and reliable, to withstand the rigors of the testing and packaging processes, and to provide a stable and effective connection in the final device. Although gate pad recess 218 is illustrated at the edge of the device similar to a mesa design and can be part of a process corresponding to dicing of the devices, the gate pad recess may be formed as a recess within epitaxial GaN layer 204 as well as other materials present in the device structure. Moreover, although the gate electrode 220 is illustrated as having a thickness such that it is coplanar with the equal to the thickness of the drain layer 216, this is not required and the thickness can be less or greater, for example, terminating at a height below the surface of the epitaxial GaN layer 204.

The at least one gate electrode 220 may comprise Cu, Au, Ti, or other suitable metals. At least one gate electrode 220 may be formed over the back surface of the epitaxial GaN layer 204 and electrically connected to the metal stack 211. Since the gates 206 are routed together at the metal stack 211, the gates 206 are electrically connected to the at least one gate electrode 220. The at least one gate electrode 220 may be electrically connected to a gate pad using, for example, wire bonding in some embodiments.

FIGS. 6A-6B illustrate top views of the back surface of the epitaxial GaN layer 204 according to some embodiments. Referring to FIG. 6A, four gate electrodes 604 (or gate pads in some embodiments) are formed on four corners of the epitaxial gallium nitride layer 204. According to some other embodiments, referring to FIG. 6B, two gate electrodes 605 are provided on two opposite corners of the epitaxial gallium nitride layer 204. The gate electrodes 604/605 may be configured as a quarter-circle, or in any other suitable geometric configuration. Although the gate electrodes are disposed in the corner as illustrated in FIGS. 6A and 6B, it will be appreciated that the positions of the gate electrodes may also be formed in other areas of back surface of the epitaxial GaN layer 204 in other embodiments. Nonetheless, the strategic placement of the corner facilitates both the fabrication process and subsequent utilization of the device.

It should be appreciated that the specific steps illustrated in FIG. 1 provides a particular method of fabricating a transistor according to an embodiment of the present invention. Other sequences of the present invention may perform the steps outlined above in different order. Moreover, the individual steps illustrated in FIG. 1 may include multiple sub-steps that may be performed in various sequences as appropriate to the individual step. Furthermore, additional steps may be added or removed depending on the particular applications. One of ordinary skill in the art would recognize many variations, modifications, and alternatives.

As mentioned above, FIG. 3 is a simplified schematic diagram illustrating an engineered substrate 300, according to an embodiment of the present invention. Engineered substrate 300 illustrated in FIG. 3 is suitable for a variety of electronic and optical applications. Engineered substrate 300 includes a core 310 that can have a coefficient of thermal expansion (CTE) that is substantially matched to the CTE of the epitaxial material that will be grown on engineered substrate 300. An epitaxial material 330 is illustrated as optional because it is not required as an element of engineered substrate 300, but will typically be grown on engineered substrate 300.

For applications including the growth of gallium nitride (GaN)-based materials (epitaxial layers including GaN-based layers), core 310 can be a polycrystalline ceramic material, for example, polycrystalline aluminum nitride (AlN), which may include binding agents, such as yttrium oxide. Other materials can be utilized as core 310, including polycrystalline gallium nitride (GaN), polycrystalline aluminum gallium nitride (AlGaN), polycrystalline silicon carbide (SiC), polycrystalline zinc oxide (ZnO), polycrystalline gallium trioxide (Ga2O3), and the like. The thickness of core 310 can be on the order of 100 to 1,500 μm, for example, 750 μm.

Core 310 may be encapsulated in a first adhesion layer 312 that can be referred to as a shell or an encapsulating shell. In an embodiment, first adhesion layer 312 comprises a tetraethyl orthosilicate (TEOS) oxide layer on the order of 1,000 Å in thickness. In other embodiments, the thickness of first adhesion layer 312 varies, for example, from 100 Å to 2,000 Å. Although TEOS oxides can be utilized for adhesion layers in some embodiments, other materials that provide for adhesion between later deposited layers and underlying layers or materials (e.g., ceramics, in particular, polycrystalline ceramics) can be utilized according to other embodiments of the present invention. For example, SiO2 or other silicon oxides (SixOy) may adhere well to ceramic materials and may provide a suitable surface for subsequent deposition, for example, of conductive materials. In some embodiments, first adhesion layer 312 completely surrounds core 310 in some embodiments to form a fully encapsulated core and can be formed using an LPCVD process or other suitable deposition processes, which can be compatible with semiconductor processing, and in particular, with polycrystalline or composite substrates and layers. In some embodiments, first adhesion layer 312 may be formed on one side of core 310. First adhesion layer 312 provides a surface on which subsequent layers adhere to form elements of the engineered substrate structure.

In addition to the use of LPCVD processes, spin on glass/dielectrics, furnace-based processes, and the like, to form the encapsulating adhesion layer, other semiconductor processes can be utilized according to embodiments of the present invention, including CVD processes or similar deposition processes. As an example, a deposition process that coats a portion of the core can be utilized; the core can be flipped over, and the deposition process could be repeated to coat additional portions of the core. Thus, although LPCVD techniques are utilized in some embodiments to provide a fully encapsulated structure, other film formation techniques can be utilized, depending on the particular application.

A conductive layer 314 is formed on first adhesion layer 312. In an embodiment, conductive layer 314 is a shell of polysilicon (i.e., polycrystalline silicon) that is formed surrounding first adhesion layer 312 since polysilicon can exhibit poor adhesion to ceramic materials. In embodiments in which conductive layer 314 is polysilicon, the thickness of the polysilicon layer can be on the order of 500-5,000 Å, for example, 2,500 Å. In some embodiments, the polysilicon layer can be formed as a shell to completely surround first adhesion layer 312 (e.g., a TEOS oxide layer), thereby forming a fully encapsulated adhesion layer, and can be formed using an LPCVD process. In other embodiments, the conductive material can be formed on a portion of the adhesion layer, for example, an upper half of the substrate structure. In some embodiments, the conductive material can be formed as a fully encapsulating layer and can be subsequently removed on one side of the substrate structure.

In an embodiment, conductive layer 314 can be a polysilicon layer doped to provide a highly conductive material. for example, conductive layer 314 may be doped with boron to provide a p-type polysilicon layer. In some embodiments, the doping with boron is at a level of 1×10¹⁹ cm⁻³ to 1×10²⁰ cm⁻³ to provide for high conductivity. Other dopants at different dopant concentrations (e.g., phosphorus, arsenic, bismuth, or the like at dopant concentrations ranging from 1×10¹⁶ cm⁻³ to 5×10¹⁸ cm⁻³) can be utilized to provide either n-type or p-type semiconductor materials suitable for use in the conductive layer. One of ordinary skill in the art would recognize many variations, modifications, and alternatives.

The presence of conductive layer 314 is useful during electrostatic chucking of the engineered substrate to semiconductor processing tools, for example tools with electrostatic chucks (ESCs or e-chucks). Conductive layer 314 enables rapid dechucking after processing in the semiconductor processing tools. In embodiments of the present invention, the conductive layer enables electrical contact with the chuck or capacitive coupling to the e-chuck during future processing including bonding. Thus, embodiments of the present invention provide substrate structures that can be processed in manners utilized with conventional silicon wafers. One of ordinary skill in the art would recognize many variations, modifications, and alternatives. Additionally, having a substrate structure with high thermal conductivity in combination with the ESD chucking may provide better deposition conditions for the subsequent formation of engineered layers and epitaxial layers, as well as for the subsequent device fabrication steps. For example, it may provide desirable thermal profiles that can result in lower stress, more uniform deposition thicknesses, and better stoichiometry control through the subsequent layer formations.

A second adhesion layer 316 (e.g., a TEOS oxide layer on the order of 1,000 Å in thickness) is formed on conductive layer 314. Second adhesion layer 316 completely surrounds conductive layer 314 in some embodiments to form a fully encapsulated structure and can be formed using an LPCVD process, a CVD process, or any other suitable deposition process, including the deposition of a spin-on dielectric.

A barrier layer 318, for example, a silicon nitride layer, is formed on second adhesion layer 316. In an embodiment, barrier layer 318 is a silicon nitride layer that is on the order of 4,000 Å to 5,000 Å in thickness. Barrier layer 318 completely surrounds the second adhesion layer in some embodiments to form a fully encapsulated structure and can be formed using an LPCVD process. In addition to silicon nitride layers, amorphous materials including SiCN, SiON, AlN, SiC, and the like can be utilized as the barrier layers. In some implementations, barrier layer 318 includes a number of sub-layers that are built up to form barrier layer 318. Thus, the term barrier layer is not intended to denote a single layer or a single material, but is to encompass one or more materials layered in a composite manner. One of ordinary skill in the art would recognize many variations, modifications, and alternatives.

In some embodiments, barrier layer 318, e.g., a silicon nitride layer, prevents diffusion and/or outgassing of elements present in the core, for example, yttrium (elemental), yttrium oxide (i.e., yttria), oxygen, metallic impurities, other trace elements, and the like, into the environment of the semiconductor processing chambers in which the engineered substrate could be present, for example, during a high temperature (e.g., 1,000° C.) epitaxial growth process. Utilizing the encapsulating layers described herein, ceramic materials, including polycrystalline AlN, that are designed for non-clean room environments, can be utilized in semiconductor process flows and clean room environments.

In some embodiments, ceramic materials utilized to form the core may be fired at temperatures in the range of 1,800° C. It would be expected that this process would drive out a significant amount of impurities present in the ceramic materials. These impurities can include yttrium, which results from the use of yttria as sintering agent, calcium, and other elements and compounds. Subsequently, during epitaxial growth processes, which may be conducted at much lower temperatures in the range of 800° C. to 1,100° C., it would be expected that the subsequent diffusion of these impurities would be insignificant. However, contrary to conventional expectations, even during epitaxial growth processes at temperatures much lower than the firing temperature of the ceramic materials, significant diffusion of elements through the layers of the engineered substrate may be present. Thus, embodiments of the present invention integrate the barrier layer into the engineered substrate structure to prevent this undesirable diffusion.

Thus, embodiments of the present invention integrate a silicon nitride layer to prevent out-diffusion of the background elements from the polycrystalline ceramic material (e.g., AlN) into the engineered layers and epitaxial layers such as optional GaN layer 330. The silicon nitride layer 318 encapsulating the underlying layers and material provides the desired barrier layer functionality. The integration of the silicon nitride layer 318 into the engineered substrate structure prevents the diffusion of calcium, yttrium, and aluminum into the engineered layers during the annealing process that occurred when the silicon nitride layer was not present. Thus, the use of the silicon nitride layer 318 prevents these elements from diffusing through the diffusion barrier and thereby prevents their release into the environment surrounding the engineered substrate. Similarly, any other impurities containing within the bulk ceramic material would be contained by the barrier layer.

A bonding layer 320 (e.g., a silicon oxide layer) may be deposited on a portion of barrier layer 318, for example, on the top surface of barrier layer 318, and subsequently used during the bonding of a substantially single crystal layer 322 (e.g., a single crystal silicon layer such as exfoliated silicon layer). Bonding layer 320 can be approximately 1.5 μm in thickness in some embodiments. In some embodiments, the thickness of bonding layer 320 is 20 nm or more for bond-induced void mitigation. In some embodiments, the thickness of bonding layer 320 is in the range of 0.75-1.5 μm.

Bonding layer 320 can be formed by a deposition of a thick (e.g., 2-5 μm thick) oxide layer followed by a chemical mechanical polishing (CMP) process to thin the oxide to approximately 1.5 μm or less in thickness. The thick initial oxide serves to smooth surface features present on the support structure that may remain after fabrication of the polycrystalline core and continue to be present as the encapsulating layers illustrated in FIG. 3 are formed. The CMP process provides a substantially planar surface free of voids, which can then be used during a wafer transfer process to bond single crystal silicon layer 322 to bonding layer 320.

The substantially single crystal layer 322 (e.g., exfoliated Si) is suitable for use as a growth layer during an epitaxial growth process for the formation of epitaxial materials. In some embodiments, the epitaxial material can include a GaN layer of 2 μm to 10 μm in thickness, which can be utilized as one of a plurality of layers utilized in optoelectronic, RF, and power devices. In an embodiment, substantially single crystal layer 322 includes a substantially single crystal silicon layer that is attached to the bonding layer using a layer transfer process.

A layer transfer process may be performed using a silicon wafer. The silicon wafer may be implanted with several elements to create a damage interface inside Si, which may help to form single crystal layer 322 for attaching to bonding layer 320. For example, applying pressure on the silicon wafer and bonding layer 320 that are attached together may atomically bond the silicon wafer to bonding layer 320.

After the bonding process, an exfoliation process may activate the damage interface inside the silicon wafer and cause the implanted elements in single crystal layer 322 to expand, thus splitting the top portion of the silicon wafer from ceramic wafer 310 with engineered layers. Remaining single crystal layer 322 bonded to bonding layer 320 may be relatively thin, such as less than around 5 microns, and therefore may not significantly contribute to the CTE of engineered substrate 300. The CTE of engineered substrate 300 is therefore primarily determined by the CTE of ceramic core 310.

Materials other than silicon may be used to create a single crystal thin bonding layer. These single crystal materials may include SiC, GaN, AlGaN, AlN, ZnO, sapphire, and other.

GaN epitaxial layer 330 (which may also be referred to as epitaxial layers) can be formed by epitaxially growing a number of layers or sub-layers to form an epitaxial structure on top of engineered substrate 300. As used herein, the term “layer” should be understood to include a structure including multiple layers or sub-layers of the same or different materials. In some embodiments, a buffer layer may be formed on bonding layer 320, and GaN epitaxial layer 330 (epitaxial layers) may be formed on top of the buffer layer. The CTEs of ceramic wafer 310 and GaN epitaxial layer 330 may be substantially matched over a wide temperature range (e.g., from about 25° C. to about 300° C.), such as within about 0.1%, 0.5%, 1%, 2%, 5%, or 10% of each other. This CTE matching enables the formation of higher quality epitaxial layers on larger ceramic wafers 310 without cracking or warping. For example, GaN epitaxial layer 330 may be formed on 6-inch, 8-inch, 3-inch, or larger engineered substrates 300. Using larger wafers may increase the device count per wafer and thus result in less expensive GaN devices.

The CTE matching may also enable the formation of a significantly thicker GaN epitaxial layer 330 (e.g., tens or hundreds of microns) on top of engineered substrate 310. The combined epitaxial layers may reduce the overall dislocation density of the lattice structures between GaN epitaxial layer 330 and single crystal layer 322. In addition, a larger number of epitaxial layers can be used to fabricate more complex circuity for a wider array of GaN devices.

Additional description related to the engineered substrate structure is provided in U.S. patent application Ser. No. 15/621,335, filed on Jun. 13, 2017, U.S. patent application Ser. No. 15/621,235, filed on Jun. 13, 2017, U.S. patent application Ser. No. 16/179,351, filed on Nov. 2, 2018, the disclosures of which are hereby incorporated by reference in their entirety for all purposes.

Although some embodiments have been discussed in terms of a layer, the term layer should be understood such that a layer can include a number of sub-layers that are built up to form the layer of interest. Thus, the term layer is not intended to denote a single layer consisting of a single material, but to encompass one or more materials layered in a composite manner to form the desired structure. One of ordinary skill in the art would recognize many variations, modifications, and alternatives.

It is understood that the examples and embodiments described herein are for illustrative purpose only and that various modifications or changes in light thereof will be suggested to persons skilled in the art and are to be included within the spirit and purview of this application and scope of the appended claims.

What is claimed is:

1. A method for fabricating a semiconductor device, the method comprising:
providing an engineered substrate including:
a polycrystalline ceramic core;
a barrier layer coupled to the polycrystalline ceramic core;
bonding layer coupled to the barrier layer; and
a substantially single crystalline layer coupled to the bonding layer;
forming an epitaxial gallium nitride layer coupled to the substantially single crystalline layer;
forming a plurality of trenches in the epitaxial gallium nitride layer;
forming a plurality of gates, each of the plurality of gates being disposed in one of the plurality of trenches;
forming a plurality of sources coupled to the epitaxial gallium nitride layer;
forming an interconnect structure on the plurality of gates and the plurality of sources, wherein the interconnect structure comprises:
an embedded metal track;
a first set of routing structures passing through the interconnect structure and electrically connecting the plurality of gates to the embedded metal track; and
a second set of routing structures passing through the interconnect structure;
forming a metal bonding layer on the interconnect structure, wherein the second set of routing structures electrically connect the plurality of sources to the metal bonding layer;
bonding a conductive carrier to the metal bonding layer;
removing the engineered substrate to expose a back surface of the epitaxial gallium nitride layer;
forming a drain layer on the back surface of the epitaxial gallium nitride layer;
etching at least one portion of the epitaxial gallium nitride layer and the interconnect structure to form at least one gate pad recess and expose the embedded metal track; and
forming at least one gate electrode in the at least one gate pad recess.

2. The method of claim 1, further comprising forming at least one gate pad attached to the at least one gate electrode.

3. The method of claim 2, wherein the at least one gate pad recess comprises two gate pad recesses, and the at least one gate pad comprises two gate pads.

4. The method of claim 1, wherein the interconnect structure comprises a first metal stack comprising a first plated bonding metal layer, the metal bonding layer comprises a second metal stack comprising a second plated bonding metal layer, and the metal bonding layer is bonded to the interconnected structure by bonding the second plated bonding metal layer to the first plated bonding metal layer.

5. The method of claim 1, wherein a depth of at least one of the plurality of trenches ranges from 0.5 μm to 2 μm.

6. The method of claim 1, wherein a depth of the at least one gate pad recess is between 5 μm and 30 μm.

7. The method of claim 1, wherein the substantially single crystalline layer comprises substantially single crystalline silicon.

8. The method of claim 1, wherein the substantially single crystalline layer comprises substantially single crystalline gallium nitride.

9. The method of claim 1, wherein the substantially single crystalline layer comprises substantially single crystalline silicon carbide.

10. The method of claim 1, wherein the conductive carrier comprises a doped silicon carrier.

11. The method of claim 10, wherein the doped silicon carrier is p-type.

12. The method of claim 10, wherein the doped silicon carrier is n-type.

13. The method of claim 1. wherein the drain layer is formed without patterning.

14. The method of claim 1. wherein the conductive carrier comprises a thick plated metal layer.

15. The method of claim 14, wherein the thick plated metal layer is characterized by a thickness ranging from 20 μm to 200 μm.
